(19) United States
(12) Patent Application Publication
(10) Pub. No.: US 2025/0299758 A1
(43) Pub. Date: Sep. 25, 2025

(54) SCAN OPERATIONS IN MEMORY DEVICES

(71) Applicant: Micron Technology, Inc., Boise, ID (US)

(72) Inventors: Fanqi Wu, Sunnyvale, CA (US); Aaron Lee, Sunnyvale, CA (US); Zhenlei Shen, Milpitas, CA (US); Tingjun Xie, Milpitas, CA (US); Juane Li, San Jose, CA (US); Jiangli Zhu, San Jose, CA (US)

(21) Appl. No.: 19/048,338

(22) Filed: Feb. 7, 2025

Related U.S. Application Data
(60) Provisional application No. 63/567,825, filed on Mar. 20, 2024.

(51) Int. Cl. G11C 29/10

(52) U.S. Cl. CPC G11C 29/10

(57) ABSTRACT

A system includes a memory device and a processing device operatively coupled to the memory device. The processing device is to perform operations including determining that a scan triggering condition has been satisfied for a block of the memory device. The operations further include setting a scan flag associated with the block to a first value indicative of satisfaction of the scan triggering condition. The operations further include delaying a scan operation of the block until an erase operation is performed on the block. The operations further include, responsive to performing the erase operation on the block, performing the scan operation on the block. The operations further include setting the scan flag associated with the block to a second value.

### REFERENCE TO RELATED APPLICATION

This application claims the priority benefit of U.S. Provisional Patent Application No. 63/567,825, filed Mar. 20, 2024, the entirety of which is incorporated herein by reference.

### TECHNICAL FIELD

Embodiments of the disclosure relate generally to memory sub-systems, and more specifically, to a tag-wait-erase select gate scan scheme.

### BACKGROUND

A memory sub-system can include one or more memory devices that store data. The memory devices can be, for example, non-volatile memory devices and volatile memory devices. In general, a host system can utilize a memory sub-system to store data at the memory devices and to retrieve data from the memory devices.

### BRIEF DESCRIPTION OF THE DRAWINGS

The present disclosure will be understood more fully from the detailed description given below and from the accompanying drawings of various embodiments of the disclosure.

FIG. 1A illustrates an example computing system that includes a memory sub-system according to some embodiments.

FIG. 1B is a block diagram of a memory device in communication with a memory sub-system controller of a memory sub-system, according to some embodiments.

FIG. 2 is a block diagram illustrating select gate devices in a data block of a memory device in a memory sub-system in accordance with some embodiments of the present disclosure.

FIG. 3 is an example graph illustrating threshold voltage degradation of a select gate device, in accordance with some embodiments of the present disclosure.

FIG. 4 is a flow diagram of an example method of performing a tag-wait-erase-scan select gate scan scheme, in accordance with some embodiments of the present disclosure.

FIG. 5 is a flow chart of a method for performing a tag-wait-erase-scan select gate scan scheme, in accordance with some embodiments of the present disclosure.

FIG. 6 is a block diagram of an example computer system in which embodiments of the present disclosure can operate.

### DETAILED DESCRIPTION

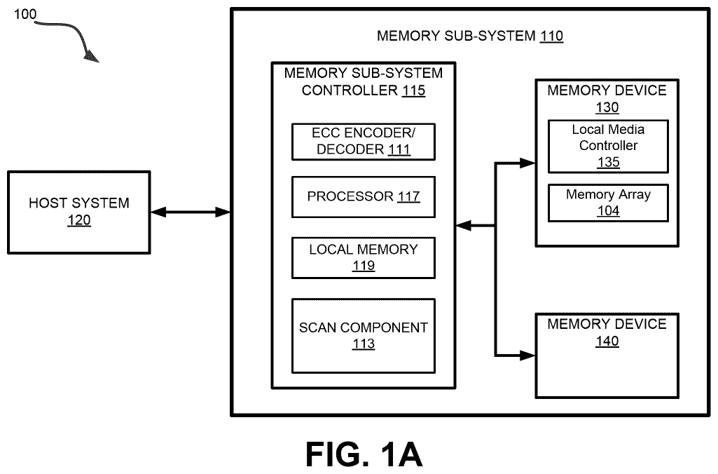

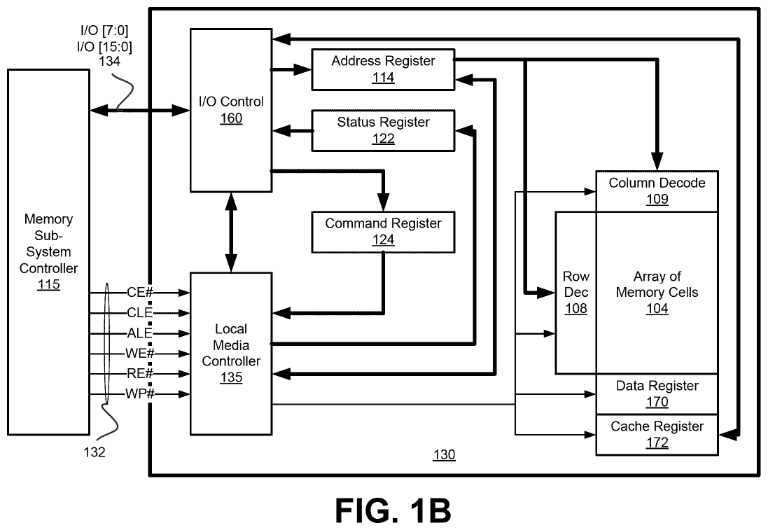

Aspects of the present disclosure are directed to a tag-wait-erase-scan select gate scan scheme (e.g., for blocks that satisfy a scan trigger condition). A memory sub-system can be a storage device, a memory module, or a combination of a storage device and memory module. Examples of storage devices and memory modules are described below in conjunction with FIGS. 1A and 1B. In general, a host system can utilize a memory sub-system that includes one or more components, such as memory devices that store data. The host system can provide data to be stored at the memory sub-system and can request data to be retrieved from the memory sub-system.

A memory sub-system can include high density non-volatile memory devices where retention of data is desired when no power is supplied to the memory device. One example of non-volatile memory devices is a not-and (NAND) memory device. Other examples of non-volatile memory devices are described below in conjunction with FIGS. 1A and 1B. A non-volatile memory device is a package of one or more dies. Each die can include of one or more planes. Each plane carries a matrix of memory cells formed onto a silicon wafer and joined by conductors referred to as wordlines and bitlines, such that a wordline joins multiple memory cells forming a row of the matric of memory cells, while a bitline joins multiple memory cells forming a column of the matric of memory cells.

For some types of non-volatile memory devices (e.g., NAND devices), each plane includes a set of physical blocks. Each block includes a set of pages. Each page includes a set of memory cells (“cells”). A cell is an electronic circuit that stores information. Depending on the cell type, a cell can store one or more bits of binary information, and has various logic states that correlate to the number of bits being stored. The logic states can be represented by binary values, such as “0” and “1”, or combinations of such values.

In non-volatile memory devices, blocks that undergo a threshold number of program/erase cycles can experience select gate threshold voltage degradation, reducing the reliability of NAND flash memory operations. Select gates in NAND flash memory can enable or block the flow of electrons to the memory cell, effectively acting as electronic switches. The select gate threshold voltage refers to the voltage level used to activate these select gates, allowing the memory cell to switch from an off state to an on state (e.g., for programming or reading). Over time, as NAND flash memory undergoes numerous program/erase cycles, the select gate threshold voltage can degrade. This degradation manifests as a shift in the voltage level necessary to activate the select gate, either increasing or decreasing the voltage level.

The shift in the voltage level affects the ability of the select gate to accurately switch. Such degradation can result from repeated program/erase cycles and/or read disturb stress (e.g., causing unintentional alteration of select gate voltage in NAND flash memory cells by voltages applied during read operations on neighboring cells). The degradation of the threshold voltage causes a shift in the charge distribution of the select gate threshold voltage. This shift can result in either an increase or decrease in charge of the select gate threshold voltage, ultimately leading to data integrity issues and operational failures.

Some select gate scan schemes are meant to identify threshold voltage degradation in select gates. However, these schemes can yield imprecise results due to variability in NAND chain resistance. NAND chain resistance originates from the cumulative electrical resistance of the interconnected memory cells within a NAND flash array. Continuous use of the device over time leads to changes and variability in NAND chain resistance (e.g., resulting from the accumulation of program/erase cycles). Inaccurate results of select gate scans can be observed in blocks that have reached a critical number of memory access operations (such as program, read, or erase operations) and are either partially or fully programmed, as these conditions significantly exacerbate the variability in NAND chain resistance (e.g., affecting scan accuracy).

Performing select gate scans on select gates affected by variability in NAND chain resistance can compromise the accuracy in detecting select gate threshold voltage degradation, leading to premature retirement of a functional block or continued use of a defective block. These inaccuracies may not only compromise device reliability by risking premature block retirement or extended use past the lifespan of the block but also may contribute directly to device failures.

Such inaccuracies can also pose significant challenges in Data Center (DC) memory devices due to the stringent performance and quality of service (QOS) requirements of DC memory devices. Some scanning methodologies may exacerbate these issues by interrupting DC memory device operations, causing increased read and write latencies and processing overhead that are particularly problematic in high-performance environments and under heavy load conditions. These approaches, when applied to blocks that are either partially or fully programmed, can interfere with host traffic, introducing more read latency that further degrading both QoS and overall system performance.

Aspects and implementations of the present disclosure aim to address these deficiencies by implementing a tag-wait-erase-scan select gate scan scheme (e.g., for blocks that satisfy a scan trigger condition). A controller of a memory device can perform select gate scan operations on blocks to identify threshold voltage degradation in the select gates of the blocks. The controller can perform these select gate scan operations on the blocks at program/erase cycle intervals. For example, the program/erase cycle interval may be every 100 program/erase cycles of the memory device.

At the program/erase cycle interval, the controller can first determine if a select gate scan triggering condition is met by the blocks before performing a select gate scan operation on the blocks. For example, if the controller determines that the select gate scan triggering condition has been satisfied for a block, a scan flag associated with the block can be set to a value (e.g., 1) that indicates that the scan triggering condition has been satisfied by the block. In some embodiments, the scan triggering condition can be a threshold value of a chosen media endurance metric (e.g., the number of program/erase cycles) exhibited by the block.

When blocks are fully or partially programmed, select gate scan operations can be inaccurate, leading to premature retirement of blocks and use of blocks beyond their functional lifespan. To avoid this, select gate scan operations can be delayed until an erase operation is performed on flagged blocks (e.g., blocks that satisfied the scan triggering condition). Following the erase operation, the select gate scan operation can be performed on the now unprogrammed (e.g., erased) blocks.

The controller can check if the flagged blocks passed the select gate scan operation, in which case the scan operation results are saved. The scan flag can then be set to a second value (e.g., 0). If the flagged blocks failed the select gate scan operation, the controller can retire the blocks as grown bad blocks.

Advantages of the present disclosure include higher accuracy in detection of select gate threshold voltage degradation by avoiding performance of select gate scan operations on blocks that have reached a critical number of memory access operations and are either partially or fully programmed. In some embodiments, the tag-wait-erase-scan scheme ensures that select gate scans are conducted on erased blocks, which has higher accuracy than scans performed on fully or partially programmed blocks. Advantages of the present disclosure further include less variability in NAND chain resistance during select gate scan operations. This helps to avoid both premature retirement of a functional block and continued use of a defective block and heightens the performance and data integrity of NAND flash memory devices. Advantages of the present disclosure further include accommodation of the stringent performance and quality of service (QoS) requirements of DC memory devices because performing select gate scans on erased blocks containing no host data does not interfere with host traffic. This eliminates read latency and enhances both QoS and overall system performance. Advantages of the present disclosure further include timely retirement of blocks with degraded select gate threshold voltages. These and other advantages will be discussed hereinafter, as would be apparent to those skilled in the art of media management.

FIG. 1A illustrates an example computing system 100 that includes a memory sub-system 110 in accordance with some embodiments of the present disclosure. The memory sub-system 110 can include media, such as one or more volatile memory devices (e.g., memory device 140), one or more non-volatile memory devices (e.g., memory device 130), or a combination of such. Each memory device 130 or 140 can be one or more memory component(s).

A memory sub-system 110 can be a storage device, a memory module, or a hybrid of a storage device and memory module. Examples of a storage device include a solid-state drive (SSD), a flash drive, a universal serial bus (USB) flash drive, an embedded Multi-Media Controller (eMMC) drive, a Universal Flash Storage (UFS) drive, a secure digital (SD) card, and a hard disk drive (HDD). Examples of memory modules include a dual in-line memory module (DIMM), a small outline DIMM (SO-DIMM), and various types of non-volatile dual in-line memory module (NVDIMM).

The computing system 100 can be a computing device such as a desktop computer, laptop computer, network server, mobile device, a vehicle (e.g., airplane, drone, train, automobile, or other conveyance), Internet of Things (IOT) enabled device, embedded computer (e.g., one included in a vehicle, industrial equipment, or a networked commercial device), or such computing device that includes memory and a processing device.

The computing system 100 can include a host system 120 that is coupled to one or more memory sub-systems 110. In some embodiments, the host system 120 is coupled to different types of memory sub-system 110. FIG. 1A illustrates one example of a host system 120 coupled to one memory sub-system 110. As used herein, “coupled to” or “coupled with” generally refers to a connection between components or devices, which can be an indirect communicative connection or direct communicative connection (e.g., without intervening components or devices), whether wired or wireless, including connections such as electrical, optical, magnetic, and the like.

The host system 120 can include a processor chipset and a software stack executed by the processor chipset. The processor chipset can include one or more cores, one or more caches, a memory controller (e.g., NVDIMM controller), and a storage protocol controller (e.g., PCIe controller, SATA controller, CXL controller). The host system 120 uses the memory sub-system 110, for example, to write data to the memory sub-system 110 and read data from the memory sub-system 110.

The host system 120 can be coupled to the memory sub-system 110 via a physical host interface. Examples of a physical host interface include, but are not limited to, a serial advanced technology attachment (SATA) interface, a compute express link (CXL) interface, a peripheral component interconnect express (PCIe) interface, universal serial bus (USB) interface, Fibre Channel, Serial Attached SCSI (SAS), a double data rate (DDR) memory bus, Small Computer System Interface (SCSI), a dual in-line memory module (DIMM) interface (e.g., DIMM socket interface that supports Double Data Rate (DDR)), etc. The physical host interface can be used to transmit data between the host system 120 and the memory sub-system 110. The host system 120 can further utilize an NVM Express (NVMe) interface to access components (e.g., memory devices 130) when the memory sub-system 110 is coupled with the host system 120 by the physical host interface (e.g., PCIe or CXL bus). The physical host interface can provide an interface for passing control, address, data, and other signals between the memory sub-system 110 and the host system 120. FIG. 1 illustrates a memory sub-system 110 as an example. In general, the host system 120 can access multiple memory sub-systems via a same communication connection, multiple separate communication connections, and/or a combination of communication connections.

The memory devices 130, 140 can include any combination of the different types of non-volatile memory devices and/or volatile memory devices. The volatile memory devices (e.g., memory device 140) can be, but are not limited to, random access memory (RAM), such as dynamic random access memory (DRAM) and synchronous dynamic random access memory (SDRAM).

Some examples of non-volatile memory devices (e.g., memory device 130) include NOT-AND (NAND) type flash memory and write-in-place memory, such as three-dimensional cross-point (“3D cross-point”) memory. A cross-point array of non-volatile memory can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased. NAND type flash memory includes, for example, two-dimensional NAND (2D NAND) and three-dimensional NAND (3D NAND).

Each of the memory devices 130 can include one or more arrays of memory cells. One type of memory cell, for example, single level cells (SLC) can store one bit per cell. Other types of MLC memory cells, such as bi-level cells (BLCs), triple-level cells (TLCs), quad-level cells (QLCs), and penta-level cells (PLCs) can store multiple bits per cell. In some embodiments, each of the memory devices 130 can include one or more arrays of memory cells such as SLCs, BLCs, TLCs, QLCs, PLCs or any combination of such. In some embodiments, a particular memory device can include an SLC portion, and an BLC portion, a TLC portion, or a QLC portion of memory cells. The memory cells of the memory devices 130 can be grouped as pages that can refer to a logical unit of the memory device used to store data. With some types of memory (e.g., NAND), pages can be grouped to form blocks.

Although non-volatile memory components such as NAND type flash memory (e.g., 2D NAND, 3D NAND) and 3D cross-point array of non-volatile memory cells are described, the memory device 130 can be based on any other type of non-volatile memory, such as read-only memory (ROM), phase change memory (PCM), self-selecting memory, other chalcogenide based memories, ferroelectric transistor random-access memory (FeTRAM), ferroelectric random access memory (FeRAM), magneto random access memory (MRAM), Spin Transfer Torque (STT)-MRAM, conductive bridging RAM (CBRAM), resistive random access memory (RRAM), oxide based RRAM (OxRAM), NOT-OR (NOR) flash memory, and electrically erasable programmable read-only memory (EEPROM).

A memory sub-system controller 115 (or controller 115 for simplicity) can communicate with the memory devices 130 to perform operations such as reading data, writing data, or erasing data at the memory devices 130 and other such operations. The memory sub-system controller 115 can include hardware such as one or more integrated circuits and/or discrete components, a buffer memory, or a combination thereof. The hardware can include a digital circuitry with dedicated (i.e., hard-coded) logic to perform the operations described herein. The memory sub-system controller 115 can be a microcontroller, special purpose logic circuitry (e.g., a field programmable gate array (FPGA), an application specific integrated circuit (ASIC), etc.), or other suitable processor.

The memory sub-system controller 115 can include a processor 117 (e.g., processing device) configured to execute instructions stored in a local memory 119. In the illustrated example, the local memory 119 of the memory sub-system controller 115 includes an embedded memory configured to store instructions for performing various processes, operations, logic flows, and routines that control operation of the memory sub-system 110, including handling communications between the memory sub-system 110 and the host system 120.

In some embodiments, the local memory 119 can include memory registers storing memory pointers, fetched data, etc. The local memory 119 can also include read-only memory (ROM) for storing micro-code. While the example memory sub-system 110 in FIG. 1A has been illustrated as including the memory sub-system controller 115, in another embodiment of the present disclosure, a memory sub-system 110 does not include a memory sub-system controller 115, and can instead rely upon external control (e.g., provided by an external host, or by a processor or controller separate from the memory sub-system).

In general, the memory sub-system controller 115 can receive commands or operations from the host system 120 and can convert the commands or operations into instructions or appropriate commands to achieve the desired access to the memory devices 130. The memory sub-system controller 115 can be responsible for other operations such as wear leveling operations, garbage collection operations, error detection and error-correcting code (ECC) operations, encryption operations, caching operations, and address translations between a logical block address (e.g., logical block address (LBA), namespace) and a physical address (e.g., physical block address) that are associated with the memory devices 130. The memory sub-system controller 115 can further include host interface circuitry to communicate with the host system 120 via the physical host interface. The host interface circuitry can convert the commands received from the host system into command instructions to access the memory devices 130 as well as convert responses associated with the memory devices 130 into information for the host system 120.

The memory sub-system 110 can also include additional circuitry or components that are not illustrated. In some embodiments, the memory sub-system 110 can include a cache or buffer (e.g., DRAM) and address circuitry (e.g., a row decoder and a column decoder) that can receive an address from the memory sub-system controller 115 and decode the address to access the memory devices 130.

In some embodiments, the memory devices 130 include local media controllers 135 that operate in conjunction with memory sub-system controller 115 to execute operations on one or more memory cells of the memory devices 130. An external controller (e.g., memory sub-system controller 115) can externally manage the memory device 130 (e.g., perform media management operations on the memory device 130). In some embodiments, the memory devices 130 are managed memory devices, which is a raw memory device combined with a local controller (e.g., the local media controller 135) for memory management within the same memory device package or memory die. An example of a managed memory device is a managed NAND (MNAND) device. Memory device 130, for example, can represent a single die or multiple dice having some control logic (e.g., local media controller 135) embodied thereon. In some embodiments, the memory device 130 includes the local media controller 135 and a memory array 104 coupled to the local media controller 135. In some embodiments, one or more components of the memory sub-system 110 are omitted.

In some embodiments, the controller 115 includes an error-correcting code (ECC) encoder/decoder 111. The ECC encoder/decoder 111 can perform ECC encoding for data written to the memory devices 130 and ECC decoding for data read from the memory devices 130, respectively. The ECC decoding can be performed to decode an ECC codeword to correct errors in the raw read data, and in many cases also to report the number of bit errors in the raw read data.

The memory sub-system 110 includes a scan component 113 that can implement a tag-wait-erase-scan select gate scan scheme for blocks that meet a scan trigger condition. In some embodiments, the memory sub-system controller 115 includes at least a portion of the scan component 113. In some embodiments, the scan component 113 is part of the host system 120, an application, or an operating system. In other embodiments, local media controller 135 includes at least a portion of scan component 113 and is configured to perform the functionality described herein.

The scan component 113 can implement a tag-wait-erase-scan select gate scan for blocks that meet a scan trigger condition. For example, the scan component 113 can set a scan flag associated with a block of memory sub-system 110 to a first value indicating that the block satisfies a scan triggering condition in response to determining that a scan triggering condition has been satisfied for the block. The scan triggering condition can be, for example, a threshold value of a chosen media endurance metric (e.g., the number of program/erase cycles) exhibited by the block. In some embodiments, the scan triggering condition can be a number of memory access operations performed on the block. The scan component 113 can delay a scan operation of the block until an erase operation is performed on the block. Because the scan operation is performed on an erased block the scan operation can be performed as a background operation. The scan component 113 can, responsive to performing the erase operation on the block, perform the scan operation on the block and either retire the block from use or retain the block for use in memory sub-system 110 based on the scan operation results. The scan component 113 can set the scan flag associated with the block to a second value.

Scan operations performed by scan component 113 to determine select gate threshold voltage degradation in NAND flash memory devices can be executed by applying a range of voltages to select gates and observing the corresponding behavior of memory cells. Initially, a predetermined voltage can be applied to the select gates across a series of memory cells within a block. This voltage can be incrementally increased or decreased, and the ability of the memory cells to retain or change their state in response to these voltage variations can be monitored. By identifying the precise voltage threshold at which memory cells begin to react inconsistently (e.g., deviating from expected conductive or non-conductive states during scan operations), degradation in the performance of the select gates can be detected. The observed threshold voltages can be compared against expected values to assess the health of the select gates. A significant shift in the voltage threshold-either higher or lower than the expected values-suggests a degradation in the select gate threshold voltage, potentially compromising the reliability of memory operations. Further details with regards to the operations of the scan component 113 are described below.

In some embodiments, the memory sub-system controller 115 includes at least a portion of the scan component 113. For example, the controller 115 can include a processor 117 (e.g., a processing device) configured to execute instructions stored in the local memory 119 for performing the operations described herein. In some embodiments, the scan component 113 is part of the host system 120, an application, or an operating system.

FIG. 1B is a simplified block diagram of a first apparatus, in the form of a memory device 130, in communication with a second apparatus, in the form of a memory sub-system controller 115 of a memory sub-system (e.g., memory sub-system 110 of FIG. 1A), according to an embodiment. Some examples of electronic systems include personal computers, personal digital assistants (PDAs), digital cameras, digital media players, digital recorders, games, appliances, vehicles, wireless devices, mobile telephones and the like. The memory sub-system controller 115 (e.g., a controller external to the memory device 130), may be a memory controller or other external host device.

Memory device 130 includes an array of memory cells 104 logically arranged in rows and columns. Memory cells of a logical row are typically connected to the same access line (e.g., a wordline) while memory cells of a logical column are typically selectively connected to the same data line (e.g., a bit line). A single access line may be associated with more than one logical row of memory cells and a single data line may be associated with more than one logical column. Memory cells (not shown in FIG. 1B) of at least a portion of array of memory cells 104 are capable of being programmed to one of at least two target data states.

Row decode circuitry 108 and column decode circuitry 109 are provided to decode address signals. Address signals are received and decoded to access the array of memory cells 104. Memory device 130 also includes input/output (I/O) control circuitry 160 to manage input of commands, addresses and data to the memory device 130 as well as output of data and status information from the memory device 130. An address register 114 is in communication with I/O control circuitry 160 and row decode circuitry 108 and column decode circuitry 109 to latch the address signals prior to decoding. A command register 124 is in communication with I/O control circuitry 160 and local media controller 135 to latch incoming commands.

A controller (e.g., the local media controller 135 internal to the memory device 130) controls access to the array of memory cells 104 in response to the commands and generates status information for the external memory sub-system controller 115, i.e., the local media controller 135 is configured to perform access operations (e.g., read operations, programming operations and/or erase operations) on the array of memory cells 104. The local media controller 135 is in communication with row decode circuitry 108 and column decode circuitry 109 to control the row decode circuitry 108 and column decode circuitry 109 in response to the addresses. In some embodiments, local media controller 135 can implement a tag-wait-erase-scan select gate scan scheme by managing memory cells in blocks within memory array 104 that satisfy a scan trigger condition, delaying scan operations on these blocks until an erase operation is performed on them and performing a scan operation on them following the erase operation. In some embodiments, the blocks within memory array 104 that satisfy a scan trigger condition can form part of a blockstripe and the erase operation can be performed on the blockstripe. Local media controller 135 can further retire the block from use or retain the block for use in array of memory cells 104 based on the scan operation results. Local medio controller can further set the scan flag associated with the block to a second value.

The local media controller 135 is also in communication with a cache register 172. Cache register 172 latches data, either incoming or outgoing, as directed by the local media controller 135 to temporarily store data while the array of memory cells 104 is busy writing or reading, respectively, other data. During a program operation (e.g., write operation), data may be passed from the cache register 172 to the data register 170 for transfer to the array of memory cells 104; then new data may be latched in the cache register 172 from the I/O control circuitry 160. During a read operation, data may be passed from the cache register 172 to the I/O control circuitry 160 for output to the memory sub-system controller 115; then new data may be passed from the data register 170 to the cache register 172. The cache register 172 and/or the data register 170 may form (e.g., may form a portion of) a page buffer of the memory device 130. A page buffer may further include sensing devices (not shown in FIG. 1B) to sense a data state of a memory cell of the array of memory cells 104, e.g., by sensing a state of a data line connected to that memory cell. A status register 122 may be in communication with I/O control circuitry 160 and the local memory controller 135 to latch the status information for output to the memory sub-system controller 115.

Memory device 130 receives control signals at the memory sub-system controller 115 from the local media controller 135 over a control link 132. For example, the control signals can include a chip enable signal CE #, a command latch enable signal CLE, an address latch enable signal ALE, a write enable signal WE #, a read enable signal RE #, and a write protect signal WP #. Additional or alternative control signals (not shown) may be further received over control link 132 depending upon the nature of the memory device 130. In some embodiments, memory device 130 receives command signals (which represent commands), address signals (which represent addresses), and data signals (which represent data) from the memory sub-system controller 115 over a multiplexed input/output (I/O) bus 134 and outputs data to the memory sub-system controller 115 over I/O bus 134.

For example, the commands may be received over input/output (I/O) pins [7:0] of I/O bus 134 at I/O control circuitry 160 and may then be written into command register 124. The addresses may be received over input/output (I/O) pins [7:0] of I/O bus 134 at I/O control circuitry 160 and may then be written into address register 114. The data may be received over input/output (I/O) pins [7:0] for an 8-bit device or input/output (I/O) pins [15:0] for a 16-bit device at I/O control circuitry 160 and then may be written into cache register 172. The data may be subsequently written into data register 170 for programming the array of memory cells 104.

In an embodiment, cache register 172 may be omitted, and the data may be written directly into data register 170. Data may also be output over input/output (I/O) pins [7:0] for an 8-bit device or input/output (I/O) pins [15:0] for a 16-bit device. Although reference may be made to I/O pins, they may include any conductive node providing for electrical connection to the memory device 130 by an external device (e.g., the memory sub-system controller 115), such as conductive pads or conductive bumps as are commonly used.

It will be appreciated by those skilled in the art that additional circuitry and signals can be provided, and that the memory device 130 of FIG. 1B has been simplified. It should be recognized that the functionality of the various block components described with reference to FIG. 1B may not necessarily be segregated to distinct components or component portions of an integrated circuit device. For example, a single component or component portion of an integrated circuit device could be adapted to perform the functionality of more than one block component of FIG. 1B. Alternatively, one or more components or component portions of an integrated circuit device could be combined to perform the functionality of a single block component of FIG. 1B. Additionally, while specific I/O pins are described in accordance with popular conventions for receipt and output of the various signals, it is noted that other combinations or numbers of I/O pins (or other I/O node structures) may be used in the various embodiments.

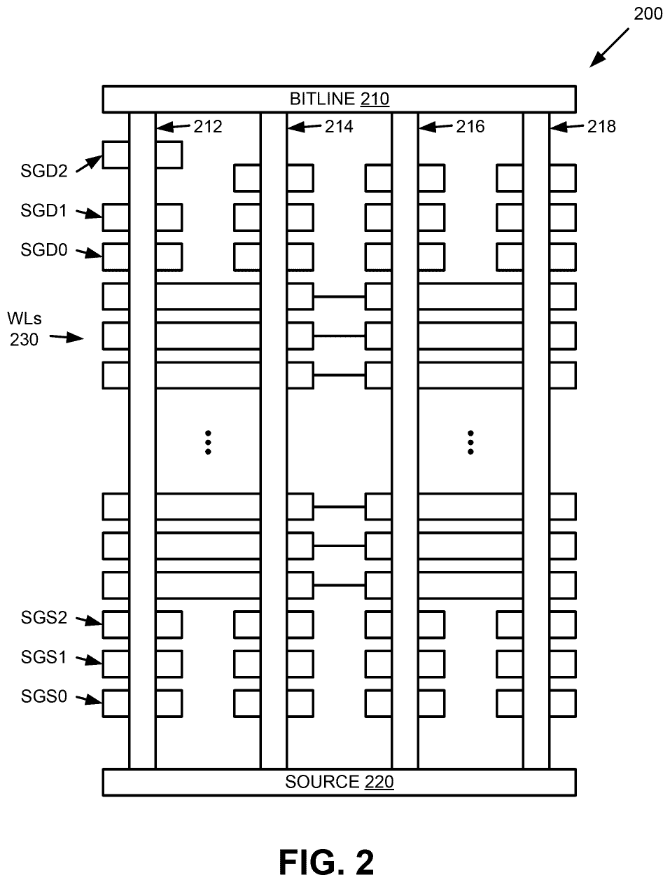

FIG. 2 is a block diagram illustrating select gate devices in a data block of a memory device in a memory sub-system in accordance with some embodiments of the present disclosure. In some embodiments, data block 200 is representative of any of the data blocks of memory device 130 or memory device 140. Data block 200 can be one of a number of physical blocks in the memory device can include a set of memory pages. The memory pages store one or more bits of binary data corresponding to data received from the host system. The memory cells of data block 200 can be arranged along a number of separate wordlines 230. Data block 200 can include a shared bitline 210 having a number of pillars 212, 214, 216, 218 extending therefrom to a separate source line 220. Each pillar can be a vertical conductive trace and the intersections of each of pillars 212, 214, 216, 218 and of each of wordlines 230 form the memory cells. Thus, each of pillars 212, 214, 216, 218 forms a separate sub-block within data block 200, where each sub-block can be access separately. To enable an access operation, such as a program operation or a read operation, to be performed on a given sub-block, data block 200 includes a number of select gate devices to selectively enable the pillar (e.g., pillar 212) associated with a certain sub-block, while disabling the pillars (e.g., pillars 214, 216, 218) associated with other sub-blocks. For example, each pillar can include a number of select gate devices (e.g., SGD0, SGD1, SGD2) at a first end (e.g., a drain end) and a number of select gate devices (e.g., SGS0, SGS1, SGS2) at a second end (e.g., a source end).

In some embodiments, select gate devices (e.g., SGD0, SGD1, SGD2) in data block 200 are specialized transistors that regulate electrical signal flow to memory cells by controlling access to sub-blocks within data block 200. Select gate devices can be positioned at the ends of pillars 212-218, these devices enable or disable specific sub-blocks for memory operations, such as reading or programming, based on their programmed threshold voltage. This selective access mechanism helps to control data storage and retrieval processes.

In some embodiments, the select gate devices in data block 200 are formed using programmable replacement gate transistors. Thus, the select gate devices have a programmed threshold voltage. Depending on a magnitude of a control signal applied relative to the threshold voltage, the select gate devices can either enable or disable the conduction of signals through the corresponding pillar. For example, if the magnitude of the control signal applied to a select gate device is less than the threshold voltage, the select gate device can be turned off and can prevent signal flow through the corresponding pillar. Conversely, if the magnitude of the control signal is greater than the threshold voltage, the select gate device can be turned on and can permit signal flow through the corresponding pillar. In some embodiments, the select gates devices associated with each pillar in data block 200 are controlled separately, such that signal flow can be prevented in certain pillars while permitted in other pillars at the same time. Replacement gate transistors have a relatively short internal channel length, and thus are susceptible to some amount of signal leakage. Accordingly, in some embodiments, each pillar in data block 200 has multiple select gate devices and each of the drain end and the source end, effectively increasing the internal channel length to provide better signal isolation when turned off.

The programmable threshold voltage of the select gate devices can shift over time. While initially set at a certain target value, numerous factors such as, a number of program/erase cycles performed on the device, changes in temperature, etc. can cause the threshold voltage of a select gate device to increase or decrease over time. This shift away from the target value can lead to charge loss causing the select gate device to function improperly, and potentially causing reliability problems in the data stored on the wordlines 230 of the corresponding sub-block.

Accordingly, in some embodiments, scan component 113 can implement a tag-wait-erase-scan select gate scan scheme for data block 200. In some embodiments, tag-wait-erase-scan select gate scan scheme includes operations where scan component 113 sets a scan flag associated with data block 200 (e.g., of memory sub-system 110) to a first value indicating that data block 200 satisfies a scan triggering condition in response to determining that a scan triggering condition has been satisfied for data block 200. The scan component 113 delays a scan operation of data block 200 until an erase operation is performed on data block 200. Because the scan operation is performed on an erased data block 200 the scan operation can be performed as a background operation. The scan component 113, responsive to performing the erase operation on data block 200, performs the scan operation on data block 200 and either retires data block 200 from use or retains data block 200 for use (e.g., in memory sub-system 110) based on the scan operation results.

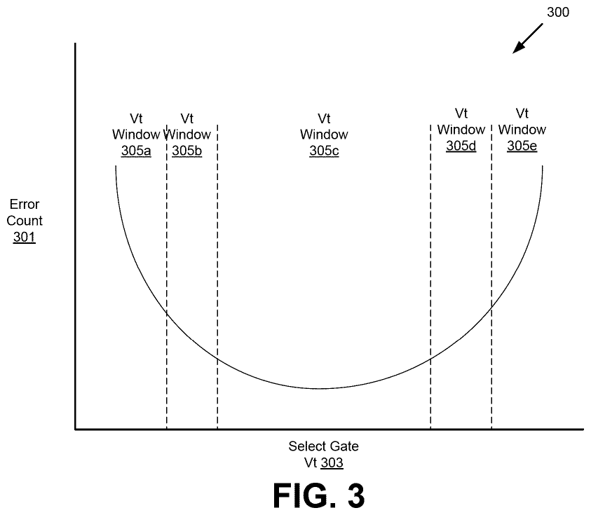

FIG. 3 is an example graph illustrating threshold voltage degradation of a select gate device, in accordance with some embodiments of the present disclosure. As illustrated, the threshold voltage of a select gate device (i.e., Select Gate Vₜ 303) can increase or decrease over time due to numerous factors, such as a number of program/erase cycles performed on the device, changes in temperature, etc. To ensure that blocks of the device are operating properly throughout the lifetime of the device and to minimize an error count of the device (i.e., error count 301), the threshold voltage of the select gate device 303 should be maintained within a target threshold voltage window, such as threshold voltage V, Window 305c. If the threshold voltage of the select gate device 303 increases, the threshold voltage can fall within a threshold voltage Vₜ Window 305d, which can lead to an increase in the error count 301 and a soft fail of the device. If the threshold voltage of the select gate 303 device increases further, the threshold voltage can fall within a threshold voltage V, Window 305c (e.g., a threshold voltage window that is higher than the V, Window 305d), which can lead to a higher increase in the error count 301 and a hard fail of the device. If the threshold voltage of the select gate device 303 decreases, the threshold voltage can fall within a threshold voltage V, Window 305b, which can lead to an increase in the error count 301 and a soft fail of the device. If the threshold voltage of the select gate device 303 decreases further, the threshold voltage can fall within a threshold voltage Vₜ Window 305a (e.g., a threshold voltage window that is lower than the Vₜ Window 305b), which can lead a higher increase in the error count 301 and a hard fail of the device.

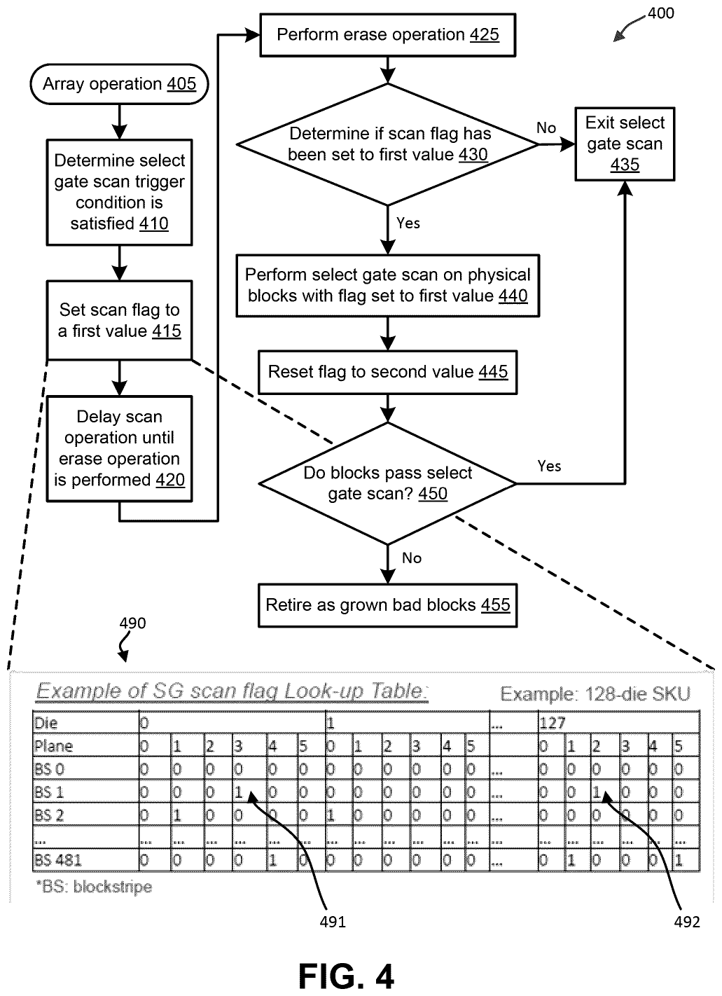

FIG. 4 is a flow diagram of an example method of performing a tag-wait-erase-scan select gate scan scheme for blocks of a memory device in that satisfy a scan trigger condition, in accordance with some embodiments of the present disclosure. The method 400 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 400 is performed by scan component 113 of FIG. 1A. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At operation 405, the processing logic receives a request to perform an array operation (e.g., a program, erase, or read operation) on a block (e.g., of memory device 130). In some embodiments, the block forms part of a blockstripe. In some embodiments, the processing logic receives a request to perform an array operation (e.g., a program, erase, or read operation) on the blockstripe (e.g., of memory device 130).

At operation 410, the processing logic determines if a scan triggering condition has been satisfied for blocks of the blockstripe. In some embodiments, the scan triggering condition can be a number of program/erase cycles performed on the block (e.g., a program/erase count (PEC)). A program/erase cycle can include data being programmed to the block and subsequently, the block being erased. This process can occur many times over the lifespan of the block, as data blocks are continually repurposed (e.g., in memory sub-system 110). In some embodiments, scan component 113, or some other component in memory sub-system controller 115 maintains a counter to track the number of program/erase operations performed on blocks (e.g., of the blockstripe). In some embodiments, the counter is maintained at a blockstripe level and is incremented each time a program/erase cycle is performed on a blockstripe. In some embodiments, the counter is initialized at an initial value (e.g., 0) and is incremented in response to program or erase operations Accordingly, the value of the counter represents the current program/erase count of a block and/or the corresponding blockstripe.

In some embodiments, the counter is initialized at an initial value (e.g., 0) and is incremented in response to the read operations. For the read triggered select gate scan, the number of reads can be tracked at drive-level (e.g., a drive containing many blocks/blockstripes). For example, the scan triggering condition can be every one-million reads.

At operation 415, the processing logic sets a scan flags associated with blocks of the blockstripe to a first value indicative of satisfaction of the scan triggering condition. If no blocks in the blockstripe satisfy the scan triggering condition then the scan flags associated with the blocks of the blockstripe are not set to the first value. In some embodiments, the processing logic stores the scan flag associated with the flagged blocks as values in a look-up table 490. In some embodiments, the processing logic stores scan flags associated with data blocks as values in the look-up table 490 to track the scan flags associated with the blocks of blockstripes. In some embodiments, a scan flag value of 1 correlates to the block satisfying the scan triggering condition and a scan flag value of 0 correlates to the block not satisfying the scan flag triggering condition.

For example, in blockstripe 1 (BS 1) two blocks are flagged. Block 491 is in plane 3 of die 0 and block 492 is in plane 2 of die 2. Each of these blocks are marked in look-up table 490 with a first value (e.g., 1). All other blocks in BS 1 did not satisfy the scan triggering condition and are therefore marked in look-up table 490 with a second value (e.g., 0) indicating that the corresponding blocks did not satisfy the scan triggering condition. In some embodiments, the block in BS 1 that did not meet the scan triggering condition can be scanned without waiting for an erase operation first.

At operation 420, the processing logic delays a scan operation of blocks of the blockstripe (e.g., block 491 and 492 of BS 1) that were flagged until an erase operation is performed on the flagged blocks. In some embodiments, the processing logic delays a scan operation of the blockstripe that includes flagged blocks (e.g., BS 1, BS 2, and BS 481 of look-up table 490) until an erase operation is performed on the blockstripe.

At operation 425, the processing logic performs the erase operation on the flagged blocks. In some embodiments, the processing logic performs the erase operation on the blockstripe that includes the flagged blocks. For example, the processing logic can perform the erase operation on block 491 and block 492 of BS 1 by performing the erase option on all of BS 1.

At operation 430, the processing logic determines if any scan flags associated with blocks of a blockstripe have been set to the first value (e.g., 1) indicative of satisfaction of the scan triggering condition.

At operation 435, if no scan flags associated with blocks of the blockstripe have been set to the first value (e.g., 1) indicative of satisfaction of the scan triggering condition, the processing logic can exit the select gate scan and save the scan results.

At operation 440, if scan flags associated with blocks of the blockstripe have been set to the first value (e.g., 1) indicative of satisfaction of the scan triggering condition, the processing logic can perform the scan operation (e.g., select gate scan operation) on the physical blocks with the flags set to the first value. For example, physical blocks 491 and 492 of BS 1 each have scan flags set to the first value (e.g., 1) in look-up table 490 indicative of satisfaction of the scan triggering condition. Therefore, the processing logic can perform the scan operation (e.g., select gate scan operation) on the physical blocks 491 and 492.

At operation 445, the processing logic resets the scan flags associated with flagged blocks of the blockstripe to a second value (e.g., 0). For example, the processing logic resets the scan flags of block 491 and 492 of BS 1 to 0.

At operation 450, processing logic determines if each individual block of the blockstripe passed the scan operation (e.g., select gate scan operation). In some embodiments, the processing logic determines if the previously flagged blocks passed the scan operation.

At operation 435, if the processing logic determines that each individual block of the blockstripe passed the scan operation, then the processing logic exits the select gate scan and saves the scan results. For example, block 491 and block 492 may have both passed the scan operation. The processing logic can save the scan results and continue using both block 491 and block 492.

At operation 455, if the processing logic determines that block(s) of the blockstripe did not pass the scan operation, processing logic retires the block(s) that did not pass the scan operation as grown bad blocks. For example, block 491 may have passed the scan operation while block 492 did not pass the scan operation. Under such circumstances, processing logic retires block 492 as a grown bad block and continues using block 491 in operations.

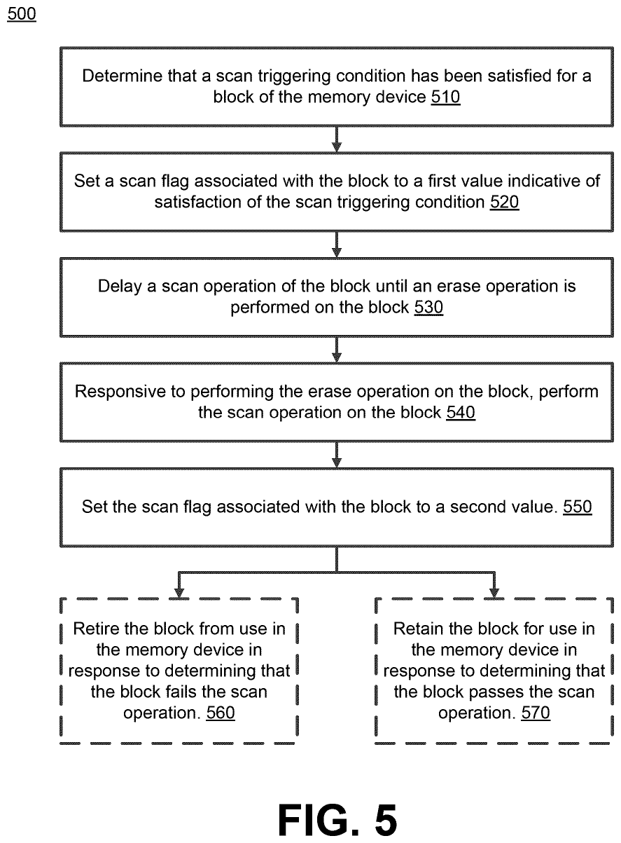

FIG. 5 is a flow chart of a method 500 for performing a tag-wait-erase-scan select gate scan scheme (e.g., for blocks of a memory device that satisfy a scan trigger condition), in accordance with some embodiments of the present disclosure. The method 500 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 500 is performed by the controller 115 (e.g., scan component 113) and/or the local media controller 135 of FIGS. 1A-1B. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At operation 510, the processing logic determines that a scan triggering condition has been satisfied for a block of the memory device. In some embodiments, the scan triggering condition is a threshold value of a chosen media endurance metric (e.g., the number of program/erase cycles) exhibited by the block. The scan triggering condition can be a threshold number of memory access operations (e.g., the number of program/erase cycles) performed on the block. In some embodiments, a blockstripe includes the block. The blockstripe can further include a plurality of blocks of the memory device.

At operation 520, processing logic sets a scan flag associated with the block to a first value indicative of satisfaction of the scan triggering condition.

At operation 530, the processing logic delays a scan operation of the block until an erase operation is performed on the block. In some embodiments, the erase operation is performed on each of a plurality of blocks of a blockstripe that includes the block.

At operation 540, the processing logic, responsive to performing the erase operation on the block, performs the scan operation on the block. In some embodiments, the scan operation is performed as a background operation. In some embodiments, a background operation is an operation that is performed during periods of low system usage or an idle state. The scan operation can be performed as a background operation because the blocks being scanned have been erased and contain no host data. Further, performing a scan operation on erased blocks does not interfere with host read traffic to the erased blocks.

At operation 550, the processing logic sets the scan flag associate with the block to a second value. In some embodiments, the processing logic of method 500 can further use a look-up table to track scan flags associated with the plurality of blocks of the blockstripe. The look-up table can be used as a dynamic registry, cataloging the scan flags for each block within the blockstripe. The look-up table is used to identify and keep track of block conditions (e.g., if the meet the scan triggering condition). In some embodiments, by continuously updating the look-up table based on the blocks satisfying or not the scan triggering condition, the processing logic can monitor the status of the blocks, facilitating the tag-wait-erase-scan select gate scan scheme.

At operation 560, the processing logic retires the block from use in the memory device in response to determining that the block fails the scan operation.

At operation 570, the processing logic retains the block for use in the memory device in response to determining that the block passes the scan operation.

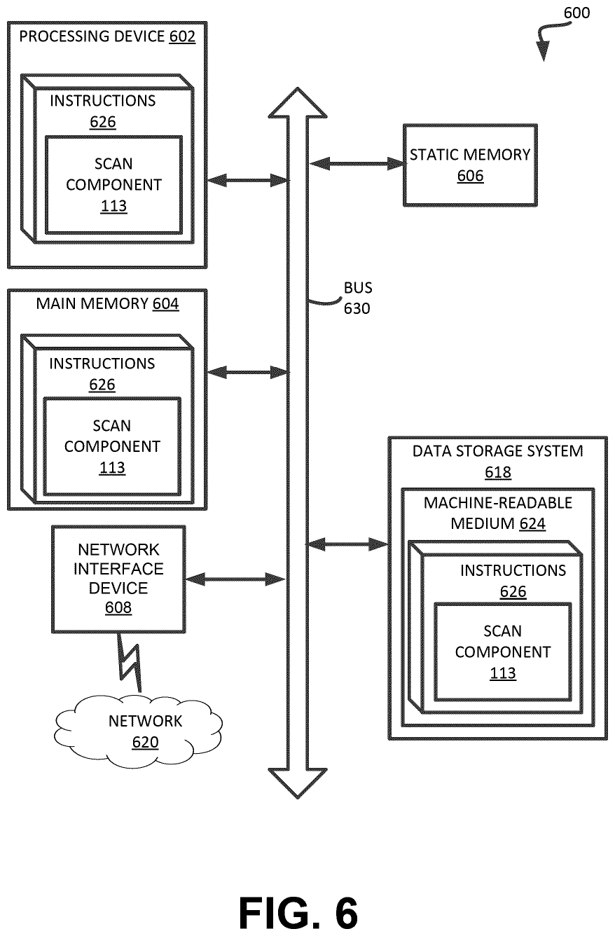

FIG. 6 illustrates an example machine of a computer system 600 within which a set of instructions, for causing the machine to perform any one or more of the methodologies discussed herein, can be executed. In some embodiments, the computer system 600 can correspond to a host system (e.g., the host system 120 of FIG. 1A) that includes, is coupled to, or utilizes a memory sub-system (e.g., the memory sub-system 110 of FIG. 1A). In alternative embodiments, the machine can be connected (e.g., networked) to other machines in a LAN, an intranet, an extranet, and/or the Internet. The machine can operate in the capacity of a server or a client machine in client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 600 includes a processing device 602, a main memory 604 (e.g., read-only memory (ROM), flash memory, dynamic random access memory (DRAM) such as synchronous DRAM (SDRAM) or Rambus DRAM (RDRAM), etc.), a static memory 606 (e.g., flash memory, static random access memory (SRAM), etc.), and a data storage system 618, which communicate with each other via a bus 630.

Processing device 602 represents one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 602 can also be one or more special-purpose processing devices such as an application specific integrated circuit (ASIC), a field programmable gate array (FPGA), a digital signal processor (DSP), network processor, or the like. The processing device 602 is configured to execute instructions 626 for performing the operations and steps discussed herein. The computer system 600 can further include a network interface device 608 to communicate over the network 620.

The data storage system 618 can include a machine-readable storage medium 624 (also known as a computer-readable medium) on which is stored one or more sets of instructions 626 or software embodying any one or more of the methodologies or functions described herein. The instructions 626 can also reside, completely or at least partially, within the main memory 604 and/or within the processing device 602 during execution thereof by the computer system 600, the main memory 604 and the processing device 602 also constituting machine-readable storage media. The machine-readable storage medium 624, data storage system 618, and/or main memory 604 can correspond to the memory sub-system 110 of FIGS. 1A-1B.

In some embodiments, the instructions 626 include instructions to implement functionality corresponding to scan component 113 of FIG. 1A. While the machine-readable storage medium 624 is shown in an example embodiment to be a single medium, the term “non-transitory computer-readable storage medium” should be taken to include a single medium or multiple media that store the one or more sets of instructions. The term “machine-readable storage medium” or “computer-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general purpose computer selectively activated or reconfigured by a computer program stored in the computer. Such a computer program can be stored in a computer readable storage medium, such as, but not limited to, any type of disk including floppy disks, optical disks, CD-ROMs, and magnetic-optical disks, read-only memories (ROMs), random access memories (RAMs), EPROMS, EEPROMs, magnetic or optical cards, or any type of media suitable for storing electronic instructions, each coupled to a computer system bus.

The algorithms and displays presented herein are not inherently related to any particular computer or other apparatus. Various general purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some embodiments, a machine-readable (e.g., computer-readable) medium includes a machine (e.g., a computer) readable storage medium such as a read only memory (“ROM”), random access memory (“RAM”), magnetic disk storage media, optical storage media, flash memory components, etc.

In the foregoing specification, embodiments of the disclosure have been described with reference to specific example embodiments thereof. It will be evident that various modifications can be made thereto without departing from the broader spirit and scope of embodiments of the disclosure as set forth in the following claims. The specification and drawings are, accordingly, to be regarded in an illustrative sense rather than a restrictive sense.

What is claimed is:

1. A system comprising:
a memory device; and
a processing device operatively coupled to the memory device, the processing device to perform operations comprising:
determining that a scan triggering condition has been satisfied for a block of the memory device;
setting a scan flag associated with the block to a first value indicative of satisfaction of the scan triggering condition;
delaying a scan operation of the block until an erase operation is performed on the block;
responsive to performing the erase operation on the block, performing the scan operation on the block; and
setting the scan flag associated with the block to a second value.

2. The system of claim 1, wherein the operations further comprise retiring the block from use in the memory device in response to determining that the block fails the scan operation.

3. The system of claim 1, wherein the operations further comprise retaining the block for use in the memory device in response to determining that the block passes the scan operation.

4. The system of claim 1, wherein the scan triggering condition is a threshold number of memory access operations performed on the block.

5. The system of claim 1, wherein the scan operation is performed as a background operation.

6. The system of claim 1, wherein a blockstripe comprises a plurality of blocks of the memory device, the plurality of blocks comprising the block, and wherein the erase operation is performed on each of the plurality of blocks of the blockstripe.

7. The system of claim 6, wherein the operations further comprise using a look-up table to track scan flags associated with the plurality of blocks of the blockstripe.

8. A method comprising:
determining, by a processing device, that a scan triggering condition has been satisfied for a block of a memory device;
setting a scan flag associated with the block to a first value indicative of satisfaction of the scan triggering condition;
delaying a scan operation of the block until an erase operation is performed on the block;
responsive to performing the erase operation on the block, performing the scan operation on the block; and
setting the scan flag associated with the block to a second value.

9. The method of claim 8, further comprising retiring the block from use in the memory device in response to determining that the block fails the scan operation.

10. The method of claim 8, further comprising retaining the block for use in the memory device in response to determining that the block passes the scan operation.

11. The method of claim 8, wherein the scan triggering condition is a threshold number of memory access operations performed on the block.

12. The method of claim 8, wherein the scan operation is performed as a background operation.

13. The method of claim 8, wherein a blockstripe comprises a plurality of blocks of the memory device, the plurality of blocks comprising the block, and wherein the erase operation is performed on each of the plurality of blocks of the blockstripe.

14. The method of claim 13, further comprising using a look-up table to track scan flags associated with the plurality of blocks of the blockstripe.

15. A non-transitory computer-readable storage medium storing instructions, which when executed by a processing device, cause the processing device to perform operations comprising:
determining that a scan triggering condition has been satisfied for a block of a memory device;
setting a scan flag associated with the block to a first value indicative of satisfaction of the scan triggering condition;
delaying a scan operation of the block until an erase operation is performed on the block;
responsive to performing the erase operation on the block, performing the scan operation on the block; and
setting the scan flag associated with the block to a second value.

16. The non-transitory computer-readable storage medium of claim 15, wherein the operations further comprise retiring the block from use in the memory device in response to determining that the block fails the scan operation.

17. The non-transitory computer-readable storage medium of claim 15, wherein the operations further comprise retaining the block for use in the memory device in response to determining that the block passes the scan operation.

18. The non-transitory computer-readable storage medium of claim 15, wherein the scan triggering condition is a threshold number of memory access operations performed on the block.

19. The non-transitory computer-readable storage medium of claim 15, wherein the scan operation is performed as a background operation.

20. The non-transitory computer-readable storage medium of claim 15, wherein a blockstripe comprises a plurality of blocks of the memory device. the plurality of blocks comprising the block, and wherein the erase operation is performed on each of the plurality of blocks of the blockstripe.
